(19) United States
(12) Patent Application Publication
(10) Pub. No.: US 2017/0104031 A1
(43) Pub. Date: Apr. 13, 2017

(54) Selector Elements

(71) Applicant: Intermolecular, Inc., San Jose, CA (US)

(72) Inventors: Mark Clark, Santa Clara, CA (US); Prashant Phatak, San Jose, CA (US); Charlene Chen, San Jose, CA (US); Ashish Bodke, San Jose, CA (US); Salil Mujumdar, San Jose, CA (US); Federico Nardi, Palo Alto, CA (US); Satbir Kahlon, Livermore, CA (US); Sergey V. Barabash, San Jose, CA (US); Feihu Wang, San Jose, CA (US)

(73) Assignee: Intermolecular, Inc., San Jose, CA (US)

(21) Appl. No.: 15/287,091

(22) Filed: Oct. 6, 2016

Related U.S. Application Data
(60) Provisional application No. 62/238,519, filed on Oct. 7, 2015.

(51) Int. Cl. H01L 27/24; G11C 11/16; G11C 13/00; H01L 45/00; H01L 27/22

(52) U.S. Cl. CPC H01L 27/2427; H01L 45/085; H01L 45/1233; H01L 45/1266; H01L 45/143; H01L 45/144; H01L 27/224; G11C 13/003; G11C 11/1659; G11C 2213/72

(57) ABSTRACT

Provided are selector elements with active components comprising insulating matrices and mobile ions disposed within these insulating matrices. Also provided are methods of operating such selector elements. The insulating matrices and mobile ions may be formed from different combinations of materials. For example, the insulating matrix may comprise amorphous silicon or silicon oxide, while mobile ions may be silver ions. In another example, the active component comprises copper and germanium, selenium, or tellerium, e.g., Se₆₁Cu₃₉, Se₆₇Cu₃₃, or Se₅₆Cu₄₄. The active component may be a multilayered structure with a variable composition throughout the structure. For example, the concentration of mobile ions may be higher in a center of the structure, away from the electrode interfaces. In some embodiments, outer layers may be formed from Ge₃₃Se₂₄Cu₄₇, while the middle layer may be formed from Ge₄₇Se₂₉Cu₂₄.

### CROSS-REFERENCE TO RELATED APPLICATIONS

This application claims the benefit under 35 U.S.C. §119(e) of U.S. Provisional Patent Application 62/238,519, entitled: “Selector Elements” filed on 2015 Oct. 7 (Attorney Docket No. IM1438_US-V), which is incorporated herein by reference in its entirety for all purposes.

### BACKGROUND

Selector elements control current flows in accordance with their internal configurations and external conditions applied to the selector elements. Two common examples of selector elements are diodes and transistors. More specific examples include Schottky diodes and Metal-Insulator-Metal Capacitor (MIMCAP) tunneling diodes. Selector elements may be also referred to as current limiters, current steering elements, or control elements. Selector elements may be used for various applications. For example, a selector element can be used in a nonvolatile memory device for screen a memory cell from sneak current paths to ensure that only selected cells in this array are read or programmed. The selector element can suppress large currents without affecting acceptable operation currents in the memory device. For example, a selector element can be used with the purpose of increasing the ratio of the measured resistances in the high and low resistance state, further making the non-volatile memory device less susceptible to the noise due to parasitic impedances in the system.

### SUMMARY

The following summary of the disclosure is included in order to provide a basic understanding of some aspects and features of the disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

Provided are selector elements with active components comprising insulating matrices and mobile ions disposed within these insulating matrices. Also provided are methods of operating such selector elements. The insulating matrices and mobile ions may be formed from different combinations of materials. For example, the insulating matrix may comprise amorphous silicon or silicon oxide, while mobile ions may be silver ions or some other ions. In another example, the active component comprises copper and germanium, selenium, or tellerium, e.g., Se₆₁Cu₃₉, Se₆₇Cu₃₃, or Se₅₆Cu₄₄. In this embodiments, copper is used as mobile ions. It should be noted that the same element of the active component may be a part of the insulating matrix and mobile ions. Furthermore, the distribution of this element between the insulating matrix and mobile ions may change during operation of the selector element. In some embodiments, the active component may be a multilayered structure with a variable composition throughout the structure. For example, the concentration of mobile ions may be higher in the center of this multilayered structure and away from the electrode interfaces. In some embodiments, outer layers may be formed from Ge₃₃Se₂₄Cu₄₇, while the middle layer may be formed from Ge₄₇Se₂₉Cu₂₄.

In some embodiments, a selector element comprises a first electrode, a second electrode, and an active component disposed between the first electrode and the second electrode. The active component comprises an insulating matrix and mobile ions. The insulating matrix may comprise one of amorphous silicon or silicon oxide. The mobile ions may comprise silver ions. The selector element may be a bipolar selector element. In some embodiments, the insulating matrix and the mobile ions comprise copper and one of germanium (Ge), selenium (Se), or tellerium (Te). More specifically, the insulating matrix and the mobile ions may comprise copper and selenium (Se). The Se:Cu atomic ratio may be between 75:25 and 50:50 or, more specifically, between 70:30 and 60:40. Even more specifically, the insulating matrix and the mobile ions comprises one of Se₆₁Cu₃₉, Se₆₇Cu₃₃, or Se₅₆Cu₄₄. In some embodiments, the first electrode directly interfaces the active component and comprises one of copper or tungsten. The second electrode may directly interface the active component and comprises copper. Alternatively, the second electrode may comprise titanium nitride.

In some embodiments, the insulating matrix and the mobile ions are arranged into a multilayered structure of the active component. At least one layer of this multilayered structure has a different composition than at least one other layer of the multilayered structure. For example, the multilayered structure may comprise a first layer, a second layer, and a third layer such that the second layer is disposed between the first layer and the third layer. The concentration of the mobile ions in the second layer may be greater than that in the first layer and in the third layer. The concentration of the mobile ions in the first layer may be substantially the same as the concentration of the mobile ions in the third layer. In some embodiments, the first layer has a composition of Ge₃₃Se₂₄Cu₄₇, the second layer has a composition of Ge₄₇Se₂₉Cu₂₄, and the third layer has a composition of Ge₃₃Se₂₄Cu₄₇. Alternatively, the multilayered structure may comprise a first layer having a composition of Ge₁₃Se₈Cu₇₉ and a second layer having a composition of Ge₆₂Se₃₈.

The mobile ions may be dispersed within the insulating matrix. In some embodiments, the mobile ions and the insulating matrix form a non-homogeneous mixture. Alternatively, the mobile ions and the insulating matrix form a homogeneous mixture. The active component may further comprise a matrix modifier comprising one of tungsten, nitrogen, or oxygen. In some embodiments, the mobile ions for a layer directly interfacing the insulating matrix.

Also provided is a method of operating a bipolar selector element. The method may comprise applying a voltage to the bipolar selector element above a threshold voltage. The bipolar selector element comprises a first electrode, a second electrode and an active component disposed between the first electrode and the second electrode and comprising an insulating matrix and mobile ions. The voltage is applied between first electrode and the second electrode. The potential of the first electrode may be greater than the potential of the second electrode. The resistance of the bipolar selector element reduces when the voltage is applied above the threshold voltage. The method then proceeds with reducing the voltage applied to the bipolar selector element below the threshold voltage. The resistance of the bipolar selector element increases when the voltage falls below the threshold voltage.

In some embodiments, the method further comprises, after reducing the voltage applied to the bipolar selector element below the threshold voltage, applying the voltage to the bipolar selector element above the threshold voltage. The voltage is applied between first electrode and the second electrode. The potential of the first electrode is less than the potential of the second electrode. The resistance of the bipolar selector element may be same as when wherein the potential of the first electrode is greater than the potential of the second electrode.

These and other embodiments are described further below with reference to the figures.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The features of the present disclosure can readily be understood by considering the following detailed description in conjunction with the accompanying drawings, in which:

FIGS. 1A and 1B are schematic illustrations of two examples a bipolar selector having an insulating matrix and mobile ions, prior to forming an initial conductive path between the electrodes, in accordance with some embodiments.

FIG. 1C is a schematic illustration of a bipolar selector after forming an initial conductive path between the electrodes, in accordance with some embodiments.

FIG. 1D is a schematic illustration of the bipolar selector of FIG. 1C after forming the initial conductive path is broken, in accordance with some embodiments.

FIG. 1E is a schematic illustration a bipolar selector showing one example of distributing an insulating matrix and mobile ions within an active component, in accordance with some embodiments.

FIG. 1F is an example of an I-V characteristic in a bipolar selector element, in accordance with some embodiments.

FIG. 2 is a J-V plot for a selector element including a copper electrode, a titanium nitride electride, and a selenium and copper containing active component.

FIG. 3 is an I-V plot for a selector element including a copper electrode, a titanium nitride electride, and a Se₆₁Cu₃₉ containing active component with titanium nitride and copper electrodes.

FIG. 4 is an I-V plot for a selector element including a copper electrode, a titanium nitride electride, and a Se₆₇Cu₃₃ containing active component with titanium nitride and copper electrodes.

FIG. 5 is an I-V plot for a selector element including a copper electrode, a titanium nitride electride, and a Se₅₆Cu₄₄ containing active component with titanium nitride and tungsten electrodes.

FIGS. 6-7 are J-V plots for a selector element including a Ge₆₆Se₃₄ containing active component.

FIG. 8A is a J-V plot for a selector element including a Ge₆₆Se₃₄ containing active component.

FIG. 8B is a J-V plot for a selector element including a Ge₂₇Se₇₃ containing active component.

FIG. 9A is a J-V plot for a selector element including a Cu₆₁Se₃₉ containing active component.

FIG. 9B is a J-V plot for a selector element including a Cu₆₇Se₃₃ containing active component.

FIG. 9C is a J-V plot for a selector element including a Cu₇₅Se₂₅ containing active component.

FIG. 9D is a J-V plot for a selector element including a Cu₄₃Se₅₇ containing active component.

FIG. 9E is a J-V plot for a selector element including a Cu₅₆Se₄₃ containing active component.

FIG. 10A illustrates a diagram identifying CuGeSe composition space suitable for selector applications.

FIG. 10B is a phase diagram identifying compositions (Cu₈GeSe₆ and Cu₂GeSe₃) in the space between Cu₆₇Se₃₃ and Ge₃₃Se₆₇.

FIG. 10C is a phase diagram in the space between Cu₆₇Se₃₃ and Ge₅₀Se₅₀.

FIG. 10D is an I-V plot for a selector element including a Cu₃₄Ge₁₄Se₅₂ containing active component.

FIG. 10E is an I-V plot for a selector element including a Cu₄₁Ge₁₁Se₄₈ containing active component.

FIG. 10F is an I-V plot for a selector element including a Cu₄₈Ge₇Se₄₅ containing active component.

FIG. 10G is an I-V plot for a selector element including a Cu₅₃Ge₇Se₄₀ containing active component.

FIG. 11A is a plot of the energy relative to the end members as a function of mole fraction in copper-selenium combinations.

FIG. 11B is a phase diagram for different compositions of copper-selenium combinations.

FIG. 12A is an I-V plot for a selector element including a Cu_{0.68}Se_{0.32} containing active component.

FIG. 12B is an I-V plot for a selector element including a Cu_{0.66}Se_{0.34} containing active component.

FIG. 12C is an I-V plot for a selector element including a Cu_{0.64}Se_{0.36} containing active component.

FIG. 12D is an I-V plot for a selector element including a Cu_{0.61}Se_{0.39} containing active component.

FIG. 12E is an I-V plot for a selector element including a Cu_{0.53}Se_{0.47} containing active component.

FIG. 13 is a phase diagram for different compositions of copper-selenium combinations.

FIG. 14A is an I-V plot (Log Scale) for a selector element including a Ge₂₀Te₂₀ containing active component.

FIG. 14B is an I-V plot (Lin Scale) for a selector element including a Ge₂₀Te₂₀ containing active component.

FIGS. 14C-14E illustrate I-V plots for different samples of the same selector design with germanium telluride containing active components showing device-to-device repeatability.

FIGS. 15A and 15B illustrate bipolar and unipolar sweeps, respectively, for a selector element with a Ge₂₀Te₈₀ containing active component having a thickness of 200 Angstroms.

FIGS. 15C and 15D illustrate bipolar and unipolar sweeps, respectively, for a selector element with a Ge₂₀Te₈₀ containing active component having a thickness of 600 Angstroms.

FIGS. 16-16D illustrate endurance data for selector elements with a Ge₂₀Te₈₀ containing active component having thicknesses of 200 Angstroms and 600 Angstroms, respectively.

FIG. 17A illustrates data for a 1T1R structure formed with a selector element with a Ge₂₀Te₈₀ containing active component.

FIGS. 17B and 17C illustrate I-V plots for a 1T1R structure cycled at a room temperature and at 85° C., respectively.

FIGS. 18A and 18B are equivalent band diagrams at zero bias and with applied high bias (above V_{NL}), respectively, for a metal/n-doped semiconductor/metal structure.

FIG. 19 is an I-V plot for a selector element with Cu_{0.51}Ge_{0.1}Se_{0.39} containing active component.

FIGS. 20A and 20B are schematic illustration of performance of various devices.

FIGS. 21A-21D is a schematic illustration of a 1T1R device and its performance characteristics.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Selector elements may be used in two terminal memory arrays to reduce/retard memory device reverse bias currents in these arrays. Specifically, a selector element may be used to avoid disturbance of unselected memory devices and to minimize the cumulative parasitic current leakage across the entire array. For unipolar memory devices, a diode (e.g., poly-silicon diode) can function as a suitable selector element. For bipolar memory devices, a selector element may need to have symmetric characteristics in both forward and reverse polarities, which is not achievable with conventional diodes. Conventional diodes simply do not have symmetric characteristics and generally cannot be used as selector elements in-line with bipolar memory elements. For purposes of this disclosure, selector elements used with bipolar memory elements are referred to as bipolar selector elements. Some characteristics of bipolar selector elements include symmetric current characteristics at forward and reverse voltage biases, low current up to a threshold voltage (low leakage current), high current above the threshold voltage (low resistance above the threshold voltage), and large current-voltage non-linearity (NL) at the threshold voltage (e.g., an increase of 4 orders of magnitude in the current value per Volt).

In some embodiments, current selectors are provided with a non-linear current-voltage (I-V) behavior, including low current at low voltages and high current at higher voltages. Unipolar selectors can be appropriate for a unipolar memory such as phase change memory (PCM), whereas bipolar selectors can be more appropriate for a bipolar memory such as resistive random-access memory (ReRAM) and spin transfer torque random access memory (STT-RAM). The unipolar selector can have high resistance in reverse polarity. Both the unipolar and the bipolar selectors can have high resistance at low voltages. These selectors can prevent sneak-through current, even when adjacent memory elements are in low-resistance state. Furthermore, the non-linear I-V can also provide the current selector with low resistance at higher voltages so that there is no significant voltage drop across the current selector during switching.

### Mobile Ion Based Selector Element

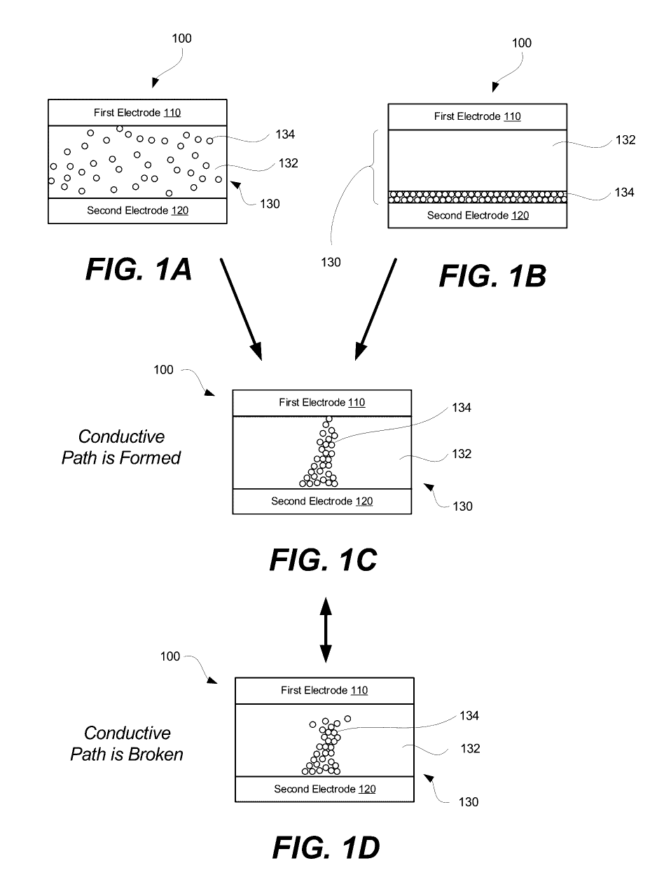

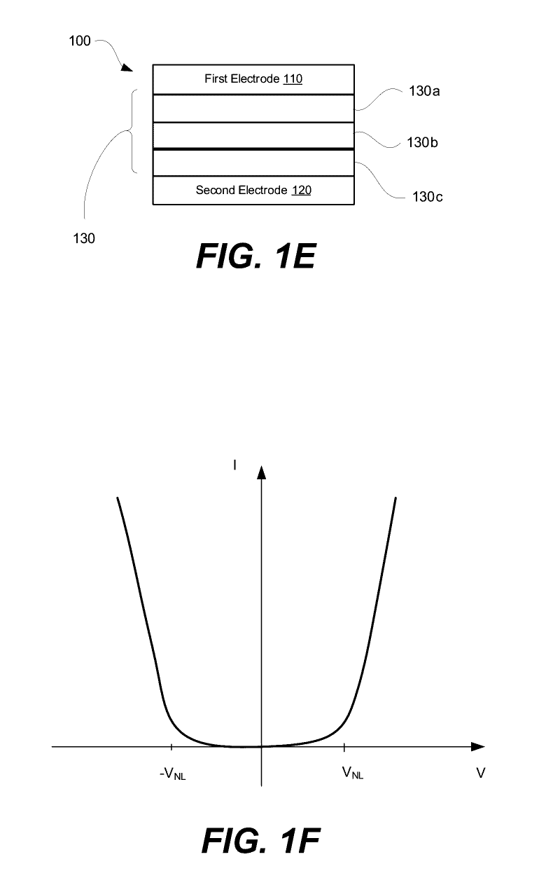

Provided are selector elements or, more specifically, bipolar selector elements suitable for memory applications and used with bipolar memory elements. Also provided are circuits including these selector elements connected in series with bipolar memory elements. A bipolar selector element may include an insulating matrix and mobile ions dispersed with the insulating matrix as will now be described below with reference to FIGS. 1A-1D.

FIGS. 1A and 1B are schematic illustrations of two examples of bipolar selector element 100 having active component 130 disposed between first electrode 110 and second electrode 120, in accordance with some embodiments. Active component 130 includes insulating matrix 132 and mobile ions 134. It should be noted the examples of bipolar selector element 100 illustrated in FIGS. 1A and 1B are prior to forming an initial conductive path between electrodes 110 and 120.

Insulating matrix 132 retards an electronic current through selector element 100. On the other hand, mobile ions 134 are used to create a current pathway through selector element 100 under the influence of an applied voltage. Specifically, at a low voltage bias, there is no current conduction through selector element 100 (the path is not formed) as, for example, schematically shown in FIGS. 1A, 1B, and 1D. At high voltage bias (e.g., at or above the threshold voltage), mobile ions 134 rearrange to create a current pathway through insulating matrix as, for example, schematically shown in FIG. 1C. When the voltage bias is reduced, the current pathway is broken due to, for example, diffusion of mobile ions 134 within insulating matrix 132 as, for example, schematically shown by transition from FIG. 1C to FIG. 1D. This characteristic, mobile ions 134 rearranging and breaking the current pathway the voltage bias is reduced is different from operation of memory cells, in which the current pathways is preserved even if voltage is completely removed and even if read voltage is applied. In other words, while memory cells strive for data retention, selector element 100 does not need such data retention, which provides additional flexibility in design and operation of selector element 100.

Without being restricted to any particular theory, it is believed that mobile ions 134 in selector element 100 being charged particles can migrate within insulating matrix 132 based on application of the external potential (bias) to insulating matrix 132 and the level of this bias. More specifically, the bias is applied to electrodes 110 and 120. Until the conductive path is formed through selector element 100, the conductivity through selector element 100 is minimal. However, when a conductive path is formed based on the influence from the external potential, the conductivity becomes high. This high conductivity (and the conductive path) is maintained until the voltage through selector element 100 remains high. Once the voltage drops, for example below the threshold voltage, mobile electrons 134 dissipate at least at the interface with one electrode as further described below. Selector element 100 allows for the discrete control of three parameters in the circuit. The first parameter is a low voltage current is determined by insulating matrix 132. The second parameter is a threshold voltage determined by the field needed to displace/move mobile ions 134 within insulating matrix 132. The third parameter is a high voltage current determined by ion formed conductive path, which may be also referred to as a filament.

While prior attempts have been made to use mobile ion insulating systems as memory elements, a fundament issue with this type of systems is the trade-off between memory endurance and data retention. Specifically, memory endurance can be improved while losing data retention or vice versa. While this trade-off may create obstacles for memory element applications, it found to be useful for selector applications. In contrast to a memory element, a selector element does not need retention and, more specifically, needs to have a poor retention. In other words, a selector element should be able to switch back to a high resistive state when the applied voltage drops below the threshold voltage. Any lag in this switching may be detrimental to the operation of the selector element. As such, the mobile ion insulator system for a bipolar selector element application may be designed with high endurance and without concerns for endurance-retention trade-off, which differentiates them from memory elements.

In some embodiments, insulating matrix 132 of bipolar selector element 100 is a highly restive semiconductor or a leaky insulator (e.g., a-Si or SiOx). Mobile ions 134 may be silver or any other suitable ions disposed within insulating matrix 132. Mobile ions 134 can be initially provided as a layer separate from insulating matrix 132 as, for example, schematically shown in FIG. 1B. Specifically, the layer of mobile ions 134 and the layer of insulating matrix 132 may be initially formed as separator component directly interfacing each other. In this example, mobile ions 134 may be dispersed within insulating matrix 132 during initial operations, e.g., a forming cycle when a high potential is applied across selector element 100. The potential may drive mobile ions 134 into insulating matrix 132 and between electrodes 110 and 120. In some embodiments, substantially all (e.g., more than 90% atomic) of mobile ions 134 may be driven into insulating matrix 132 during this forming cycle. The forming cycle may be performed at elevated temperatures to improve diffusion of mobile ions 134 in insulating matrix 132. Furthermore, a potential and, in some embodiments, duration of the forming cycle may be much longer than that of the operating cycle.

Alternatively, mobile ions 134 may be dispersed in insulating matrix 132 during initial fabrication insulating matrix 132 and before forming the initial conductive path as, for example, schematically shown in FIG. 1A. In these embodiments, mobile ions 134 ions may be dispersed within insulating matrix 132 without forming any defined conductive paths. Mobile ions 134 may still need to be rearranged within insulating matrix 132 to form an initial conductive paths.

In some embodiments, active component 130 may have multiple layers 130a-130c such that at least two of these layers have different compositions. This approach may be referred to as partitioning. The partitioning allows for discrete compositional control throughout the thickness of active component 130. For example, active component 130 may be a tri-layered stack as shown in FIG. 1E including mobile ion rich layer 130b at the center of this stack surrounded by two ion poor layers 130a and 130c. In this example, ion poor layers 130a and 130 directly interface electrodes 110 and 120.

Returning to FIGS. 1A and 1B, while forming a conductive path from mobile ions 134 dispersed in insulating matrix 132 (FIG. 1A) may be appear easier and may require a lower forming voltage than from mobile ions 134 initially arranged as a separate layer adjacent to insulating matrix 132 (FIG. 1B), the shape of the conductive path formed from mobile ions 134 initially positioned in the separate layer may be more preferable from performance perspective of selector element 100. Specifically, this shape may have a substantial taper toward one electrode (second electrode 120 referring to FIGS. 1B and 1C) and it may be easier for the conductive path to brake when no bias is applied.

Referring to FIG. 1C, applying a voltage potential between electrodes 110 and 120 creates an electric field across insulating matrix 132. Charged mobile ions 134 responded to the polarity and magnitude of this electric field. In a sufficiently high field, mobile ions 134 will migrate through insulating matrix 132. This migration is governed by the size of mobile ions 134 and the crystal lattice dimension of the material of insulating matrix 132. For example, when mobile ions 134 are driven in a direction from second electrode 120 to first electrode 110, mobile ions 134 will eventually reach first electrode 110 where they will be neutralized by an electron and come to rest as a metal. The newly formed metal in selector element 100 reduces distance between two electrodes 110 and 120, thus providing a preferential site (reduced distance to travel) for the next ion to arrive. As the process is repeated, a pseudo-metallic filament is formed atom by atom through the resistive matrix. The resulting filament provides a low resistance path for current conduction as, shown in FIG. 1C.

The formation process of the filament will be self-limiting, because as the filament becomes more conductive, the electric field will drop, thus reducing the potential driving the ion motion. The initial formation of a filament will likely require a longer duration and higher field than subsequent cycles, owing to the distance and number of ions that are required to complete the initial pseudo-filament forming process.

When the voltage bias is removed, the meta-stable tip of the filament will retract to reduce the surface area in contact with the insulating material of the matrix, as schematically shown in FIG. 1D. This behavior is result of the material selection, such that the metal formed by mobile ions 134 is not soluble in the material of insulating matrix 132. As a result of the filament retraction, the electrical resistivity of the stack increases. It should be noted that the resulting resistance may be not as high as initially prepared selector element 100 as, for example, shown in FIGS. 1A and 1B. Subsequent application of voltage bias creates an electric field across the gap between the filament and the opposing electrode, and in response to the field, the filament tip is reformed and the resistance is low again. As the stack is symmetric this process behaves the same in forward or reverse bias. For example, application of a reverse bias to a selector element that had already been formed with a forward bias would result in ion motion from the opposite electrode, but in near the same location as the original filament. FIG. 1F illustrates an example of I-V characteristic for a bipolar selector element.

As described above, a bipolar selector element may include an insulating matrix and mobile ions than can form a current pathway (e.g., ionic or induce electronic) through the insulating matrix. In some embodiments, the bipolar selector element may also include a mobile ion reservoir created by one or both of the electrodes. For example, the electrode may be formed from copper or include substantial amounts copper (e.g., be copper doped electrode), e.g., between about 10% and 90% atomic or even between about 20% and 80% atomic. In this example, mobile ions may be copper ions. The insulating matrix may include selenide. The other electrode may be titanium nitride and may be referred to as an inert electrode as it does not supply or remove mobile ions from the insulating matrix.

As described above, at a low voltage bias there is no or very little current conduction through the bipolar selector element. At this point, the bipolar selector element behaves effectively as an insulator or a resistive semiconductor. On the other hand, at a high voltage bias (e.g., at a threshold voltage or above the threshold voltage, the mobile ions migrate and form a current pathway. The migration may be due to ionic motion and/or the creation of electronic carriers.

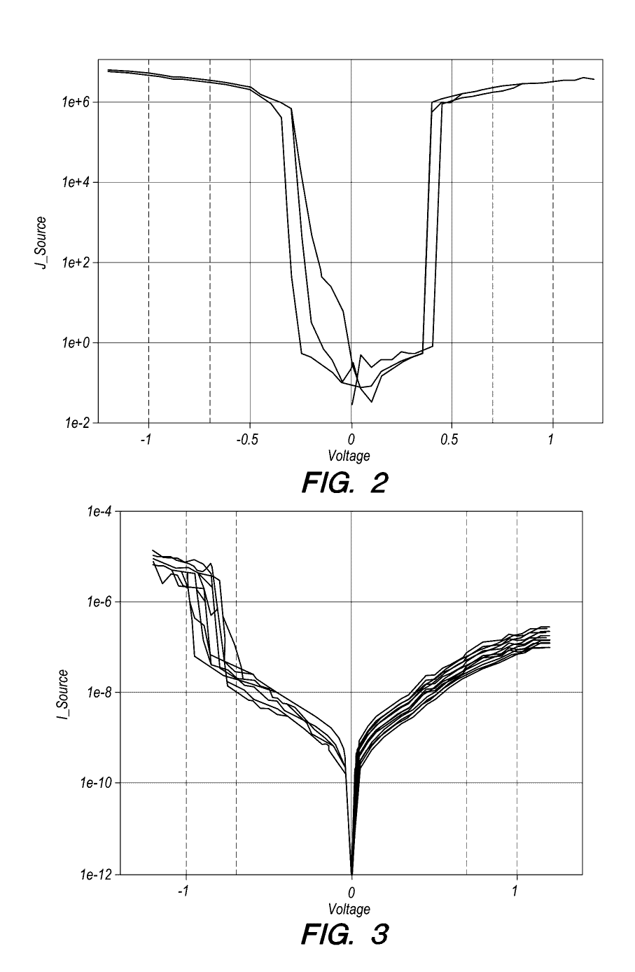

FIG. 2 is a a J/V plot for Cu/SeₓCuₓ/TiN selector element. As noted by abbreviation Cu/SeₓCuₓ/TiN, this selector element include one copper electrode, one titanium nitride element, and copper selenide-containing active component disposed between the two electrode. Depending on the concentration of copper in copper selenide, it may be viewed as an insulating matrix or as an insulating layer including mobile ions (i.e., the active component). FIG. 2 depicts the non-linear behavior in forward and reverse polarity for this selector element. In general, the insulating matrix include copper (Cu) and any combination of germanium (Ge), selenium (Se), and tellerium (Te). In some embodiments, the insulating matrix may be a non-homogeneous mixture of different components. Furthermore, matrix modifiers, such as tungsten (W), nitrogen (N) and oxygen (O) can be added to the insulating matrix to reduce its leakage. The concentration of these matrix modifiers may be between about 1% and 5% atomic.

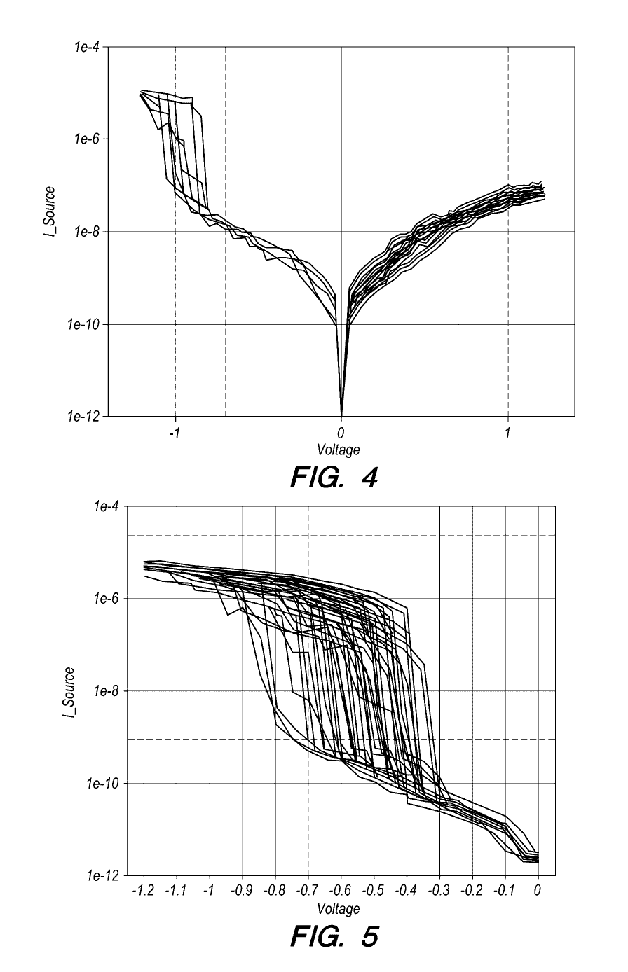

In some embodiments, the insulating matrix may include selenium and copper. More specifically, the insulating matrix may consist essentially of selenium and copper. The concentration of other elements in the insulating matrix may be less than 5% atomic or even less than 1% atomic. In some embodiments, the insulating matrix may include more selenium than copper. For example, the composition of the insulating matrix may be Se₆₁Cu₃₉, Se₆₇Cu₃₃, and Se₅₆Cu₄₄. FIG. 3 is an I-V plot for a selector element including a copper electrode, a titanium nitride electride, and a Se₆₁Cu₃₉ containing active component with titanium nitride and copper electrodes. FIG. 4 is an I-V plot for a selector element including a copper electrode, a titanium nitride electride, and a Se₆₇Cu₃₃ containing active component with titanium nitride and copper electrodes. FIG. 5 is an I-V plot for a selector element including a copper electrode, a titanium nitride electride, and a Se₅₆Cu₄₄ containing active component with titanium nitride and tungsten electrodes. These figures indicate even though, the active component include copper (in the form on copper selenide), neither one of the electrodes need to include copper. Specifically, W/Se₅₆Cu₄₄/TiN selector element performed comparable to Cu/Se₆₁Cu₃₉/TiN selector element and Cu/Se₆₇Cu₃₃/TiN selector element. Furthermore, relative amount of copper and selenium in the active component may vary over some range.

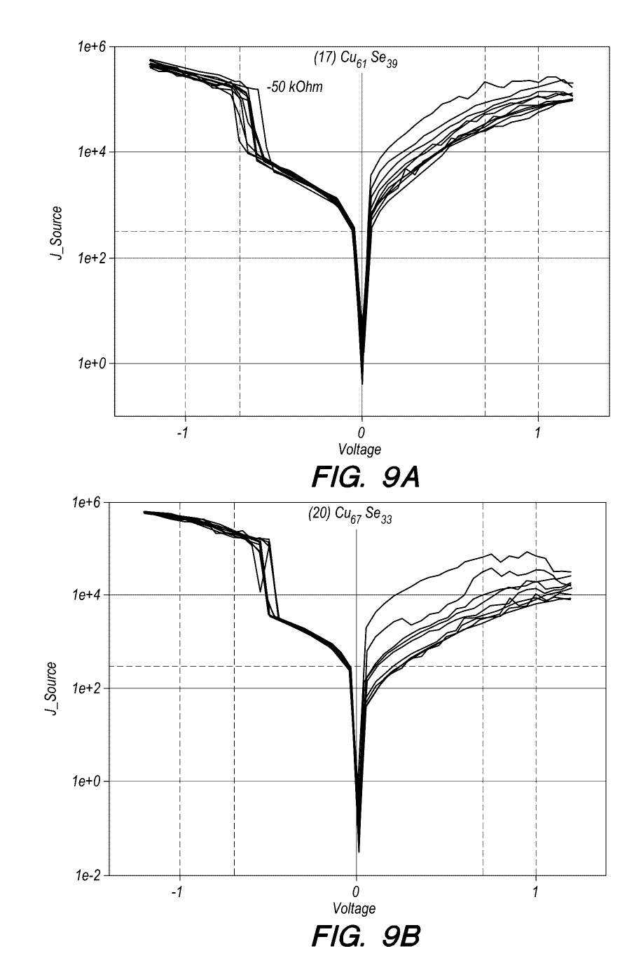

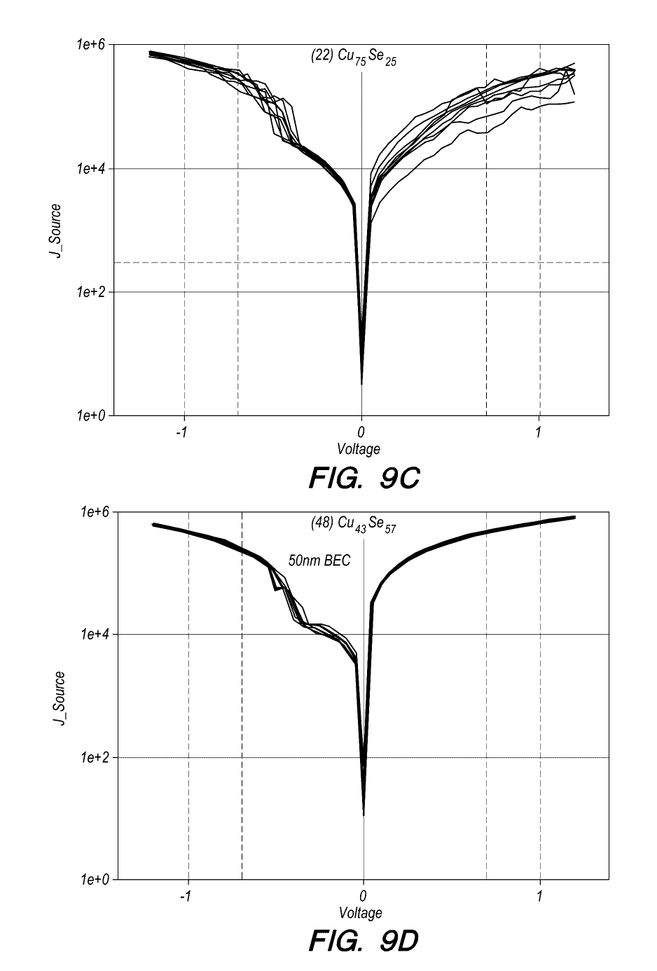

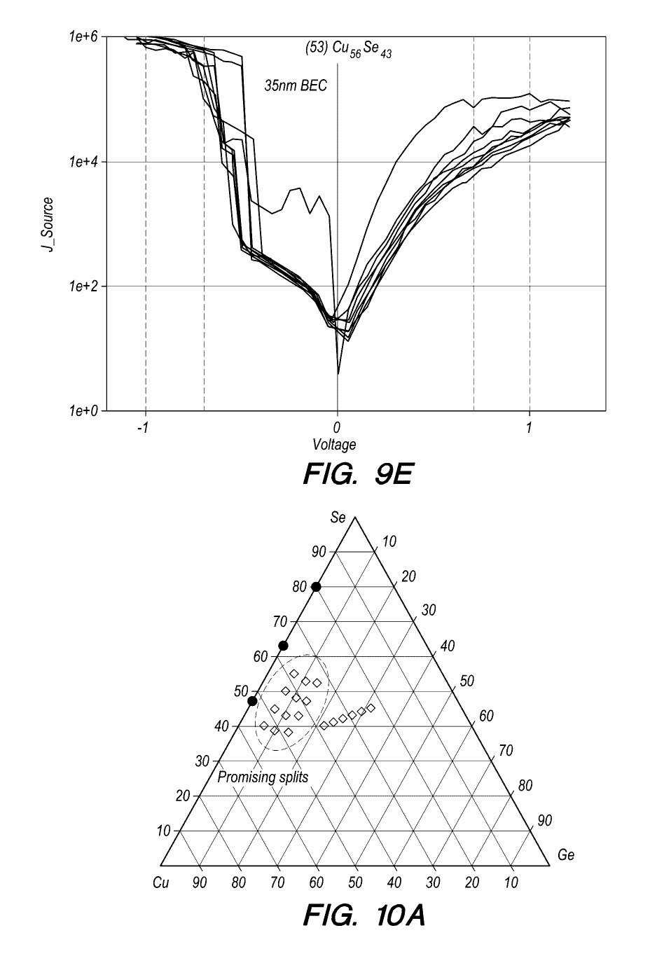

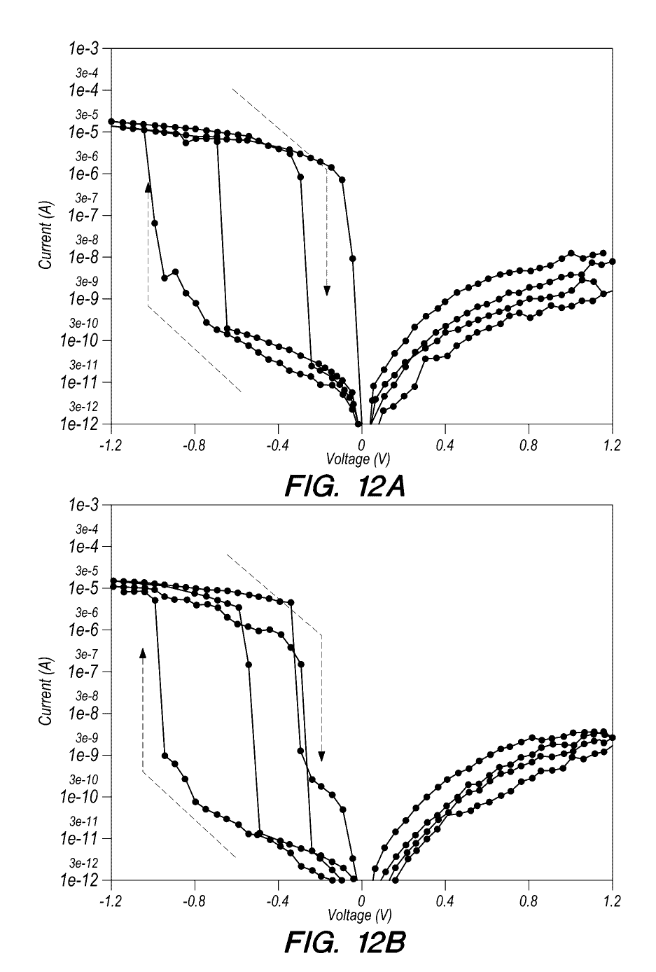

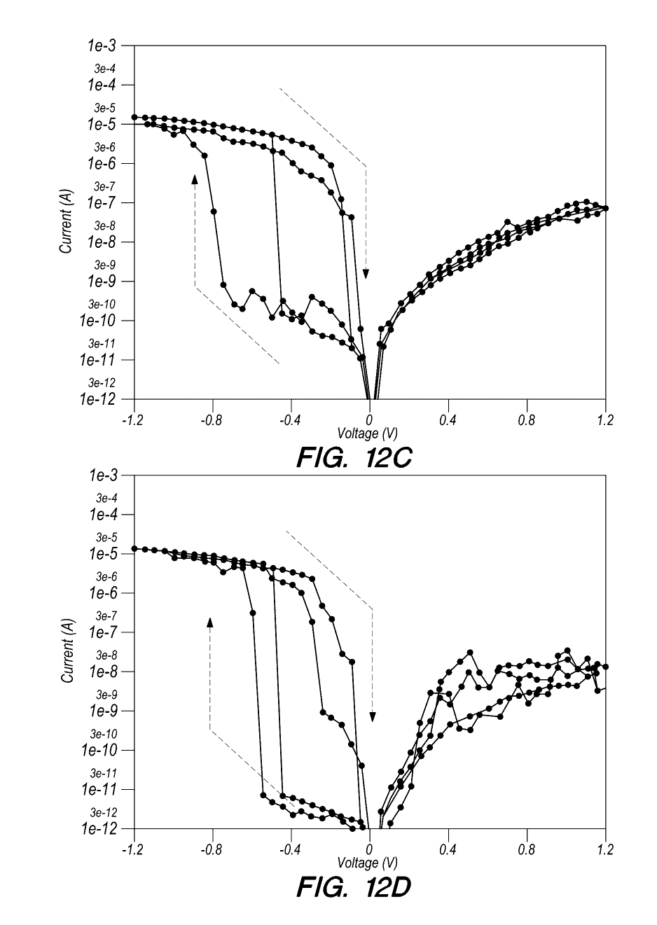

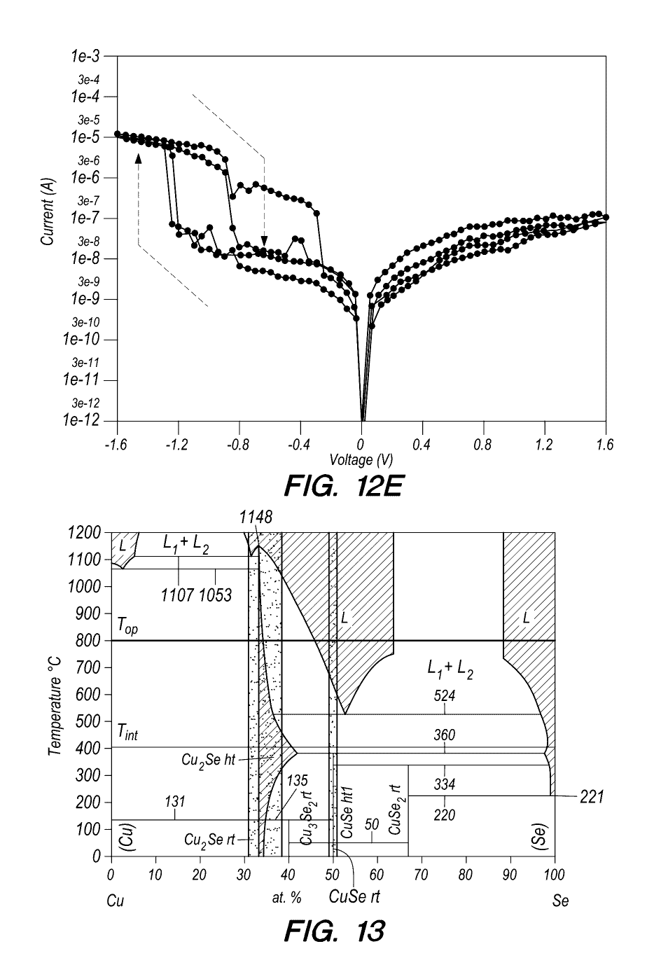

In some embodiments, the insulating matrix may include more copper than selenium. For example, the composition of the insulating matrix may be Cu₆₁Se₃₉, Cu₆₇Se₃₃, Cu₇₅Se₂₅, Cu₄₃Se₅₇, and Cu₅₆Se₄₃. FIG. 9A is a J-V plot for a selector element including a Cu₆₁Se₃₉ containing active component. FIG. 9B is a J-V plot for a selector element including a Cu₆₇Se₃₃ containing active component. FIG. 9C is a J-V plot for a selector element including a Cu₇₅Se₂₅ containing active component. FIG. 9D is a J-V plot for a selector element including a Cu₄₃Se₅₇ containing active component. FIG. 9E is a J-V plot for a selector element including a Cu₅₆Se₄₃ containing active component. FIGS. 12A-12E further described below illustrate examples in which the insulating matrix includes more copper than selenium.

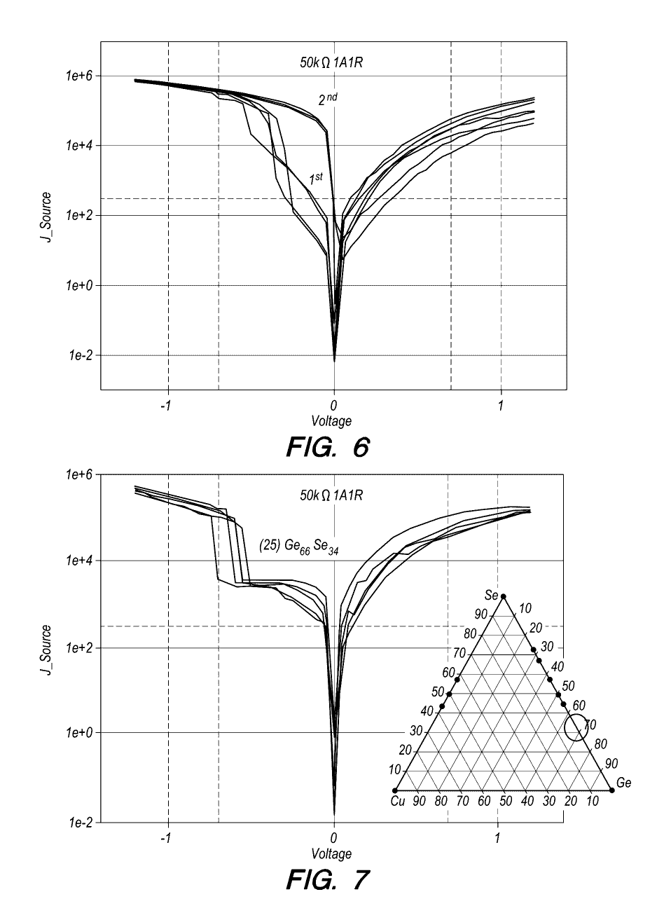

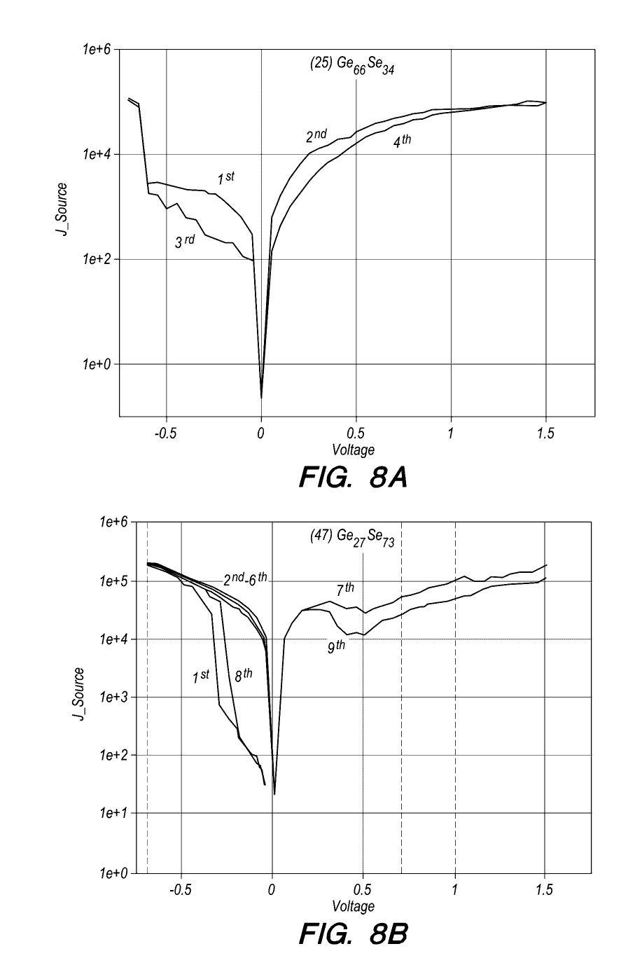

FIGS. 6-7 are J-V plots for a selector element including a Ge₆₆Se₃₄ containing active component. These figures show elastic cycling (no hysteresis) behavior, which indicates that this material can be used as a selector element. At that same time, a conventionally used equimolar GeSe, which is different from Ge₆₆Se₃₄, show a hysteresis after the first non-linear event. As such, Ge₆₆Se₃₄ and various other combination of germanium and selenium described herein can be used as a memory element, while others cannot. As stated above, forming a symmetric stack may yield symmetric I-V characteristics. Overall, a circuit may be formed in which selector is formed from Ge₆₆Se₃₄ while a memory element is formed from GeSe. This combination of materials and operating components can be obtained by varying relative concentrations of Ge and Se (e.g., varying powers while sputtering two targets). An additional composition of the insulating matrix include Ge₂₇Se₇₃. FIG. 8A is a J-V plot for a selector element including a Ge₆₆Se₃₄ containing active component. FIG. 8B is a J-V plot for a selector element including a Ge₂₇Se₇₃ containing active component. FIG. 8 illustrates experimental data for Ge₂₇Se₇₃. This data indicates that bipolar sweeps can recover the reverse non-linearity for Ge₂₇Se₇₃. As such, Ge₂₇Se₇₃ can be used as non-volatile memory elements.

Overall, selector elements described herein exhibit a symmetric current response at low voltages. Furthermore, these selector elements exhibited a non-linear increase in current at the threshold voltage. Because the current increased non-linearly, the current was asymmetric above the threshold voltage. Finally, these selector elements showed elastic cycling without hysteresis or memory effect.

In some embodiments, the selector element is asymmetrical. For example, in asymmetrical control elements, one electrode interface can have a high barrier height and the other electrode interface can be Ohmic. Alternatively, the asymmetrical selector element may include addition of bulk or interfacial defects which can allow tunneling through the Schottky barrier.

Some types of selector elements, such as poly-silicon diodes, require high temperature processing (e.g., >450 C) that is incompatible with the underlying CMOS circuitry. Provided are selector elements that can be formed using lower temperatures, such as less than 600° C. or even less than 450° C. These selectors are suitable for emerging non-volatile memory architectures such as ReRAM, PCM and STT-RAM, which are further described below.

As described above, a selector element may include three primary components. One component is an insulating matrix that retards the electronic current. Another component is mobiles ions than can create a current pathway (e.g., ionic or induce electronic) across the insulating matrix under the influence of an applied voltage. A combination of the mobile ions and insulating matrix may be referred to as an active component of the selector element. The third component is electrodes. The active component is disposed between two electrodes. At low voltage bias there is no current conduction through a selector element, and it behaves as an insulator or as a very resistive semiconductor. At high voltage bias (e.g., at or above the threshold voltage), the mobile ions migrate generating a current pathway through ionic motion and/or the creation of electronic carriers.

As stated above, the active component may include copper (Cu) and any combinations of germanium (Ge), selenium (Se), copper (Cu), and tellurium (Te). For example, a combination of selenium and copper with Se:Cu ratios between 75:25 and 50:50 may be used. These combinations of selenium and copper exhibit asymmetric selector behavior. Additionally, these compositions are capable of greater than 100 cycles as shown in FIG. 5.

As stated above, the matrix need not be a homogeneous mixture of the constituent elements. Matrix modifiers of W, N and O can be added to modulate the low voltage current as well as the threshold voltage.

As described above with reference to FIG. 1E, the active component may include two or more layers having different composition, which may be referred to as partitioning. The partitioning allows for discrete compositional control throughout the thickness of the active component. For example, the active component may me a tri-layered structure consisting of a mobile ion rich layer at the center surrounded by between two ion poor layers such as, two outer layers have a composition of Ge₃₃Se₂₄Cu₄₇, while the center layer has a composition of Ge₄₇Se₂₉Cu₂₄. This stack may be referred to as Ge₃₃Se₂₄Cu₄₇/Ge₄₇Se₂₉Cu₂₄/Ge₃₃Se₂₄Cu₄₇. In this example, copper is operable as mobile ions. Other stacks are also within the scope.

This layered approach allows for discrete placement of the mobile ions to tune the selector performance. By preferentially locating the mobile ions, it is possible to alter the threshold voltage as well as the triggering time. Additionally, the ion rich layers can act as fixed concentration ion reservoirs in order to control the total amount of mobile ions allowed into the ion poor system, and thus preventing a saturation of ion that would occur from an infinite source (e.g., metal source).

The order and number of semiconductor/insulator layers is adjustable. For example, if by only using two layers, one rich in mobile ions and the other deficient, the device I/V response could be made asymmetric (diode like). The composition of any one layer can be adjusted through the full range of the CuGeSe ternary system. For mobile ion rich layers, the composition is greater than 40% Cu (e.g, Ge₁₃Se₈Cu₇₉). By contrast, the composition in the ion poor regions is less than 60% Cu (e.g., Ge₆₂Se₃₈Cu₀₀). Additionally, the composition can be further modified by O, N or W to reduce the electronic transport or retard ion motion.

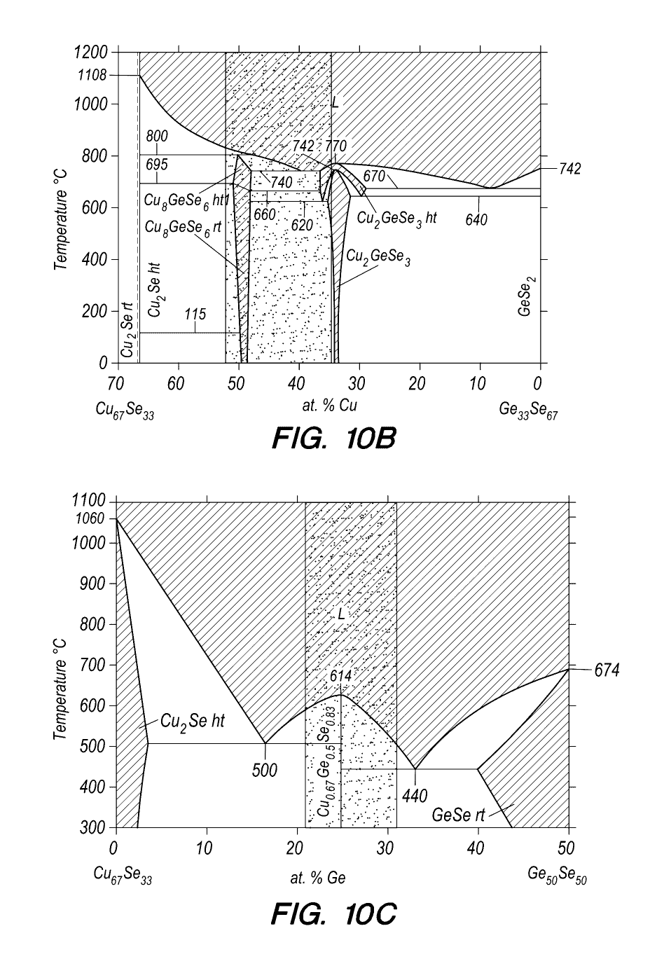

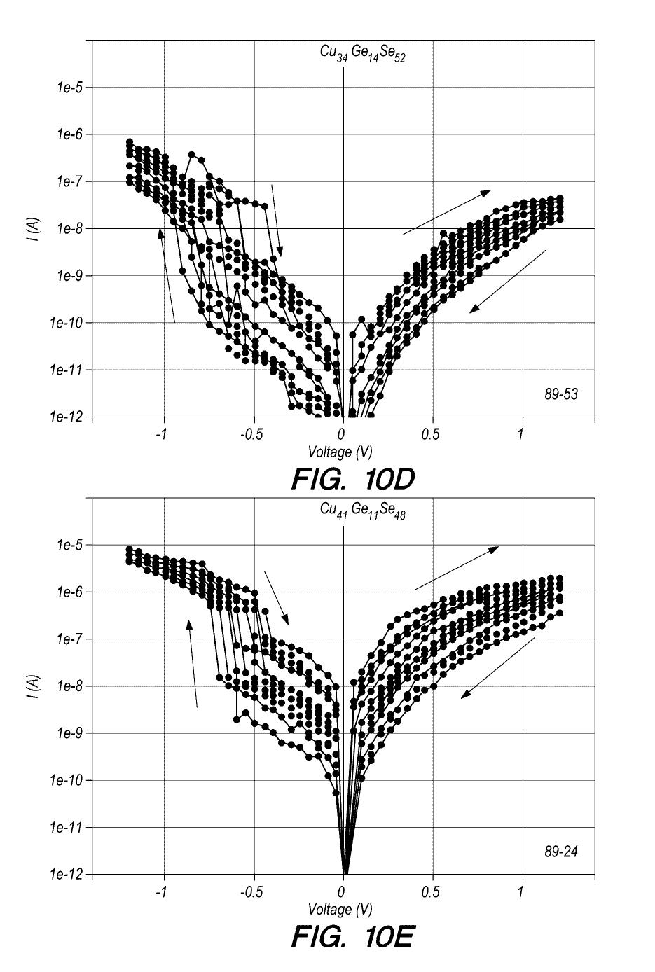

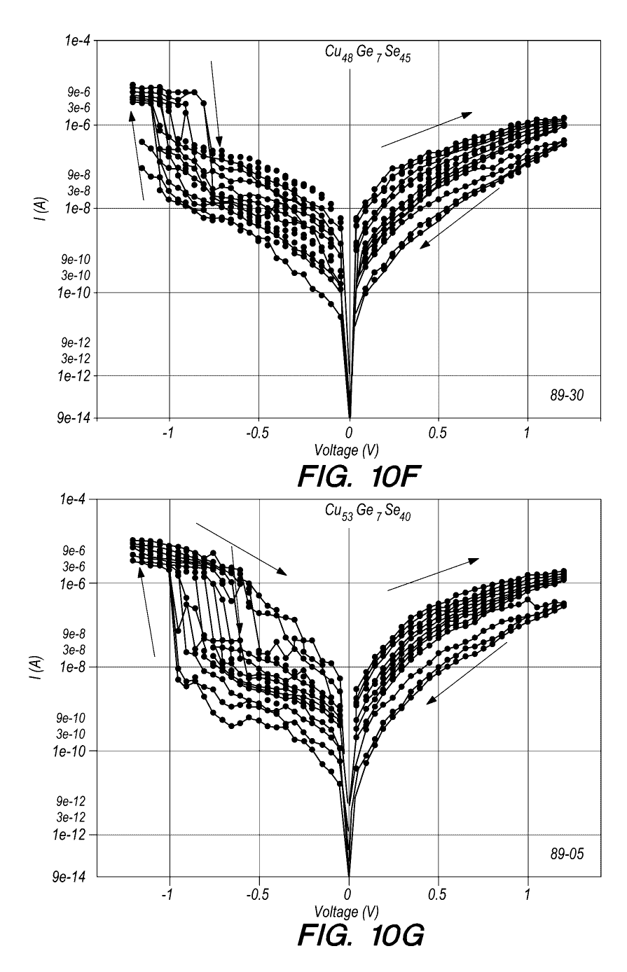

In some embodiments, ternary systems may be used for active components of selector element. For example, Cu₈GeSe₆ and Cu₂GeSe₃ phases may be utilized for achieving selector behavior. FIGS. 10A-10C illustrate CuGeSe composition space suitable for selector applications. Wide composition skew around Cu₈GeSe₆ and Cu₂GeSe₃ for obtaining selector behavior. FIGS. 10D-10G illustrate selector behavior for CuGeSe phases used with tungsten and titanium nitride electrodes. This behavior shows small hysteresis and low pre-voltage at non-linear event (VNL) leakage. Furthermore, no reset was seen in positive sweeps.

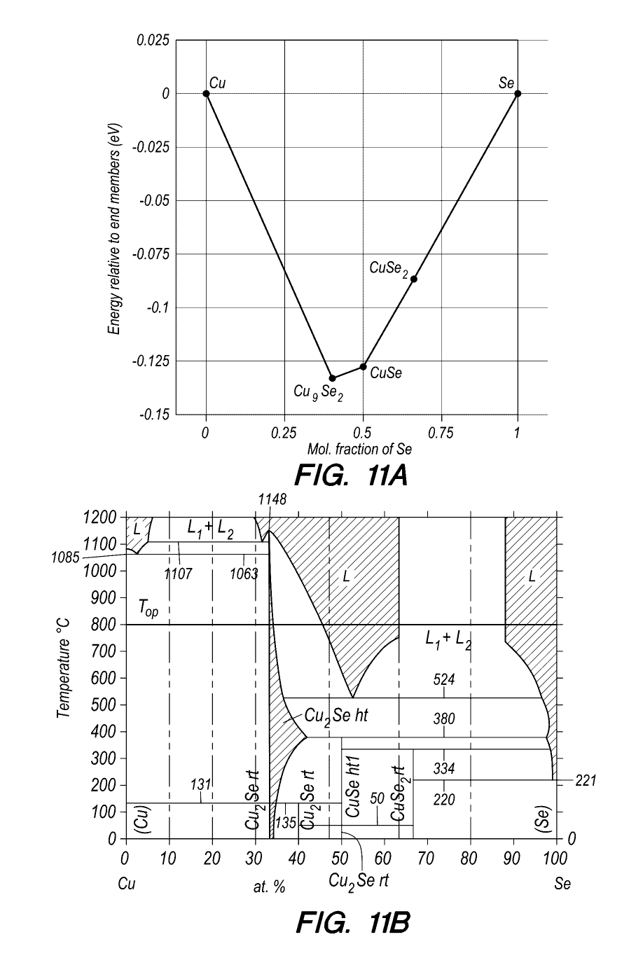

Functionality of memory selector elements based on predicted thermodynamically stable phase materials (CuₓSe_{y} systems) is presented in FIGS. 11A-11B and 12A-12E. Specifically, FIG. 12A is an I-V plot for a selector element including a Cu_{0.68}Se_{0.32} containing active component. FIG. 12B is an I-V plot for a selector element including a Cu_{0.66}Se_{0.34} containing active component. FIG. 12C is an I-V plot for a selector element including a Cu_{0.64}Se_{0.36} containing active component. FIG. 12D is an I-V plot for a selector element including a Cu_{0.61}Se_{0.39} containing active component. FIG. 12E is an I-V plot for a selector element including a Cu_{0.53}Se_{0.47} containing active component. It should be noted that PVD co-sputtering and/or combinatorial approaches may be used cover the entire compositional ternary diagram. Calculated phase diagrams presented in FIGS. 11A-11B and 12A-12E provide representative examples of possible stable configurations. In order to have an electronic/ionic device, i.e. phase transformation/segregation after 400 C integration anneal and during the operation of the device itself (e.g. ˜800 C due to Joule heating) should be avoided. Some specific examples of stable phase memory materials for selector applications include Cu_{0.66}Se_{0.34} and Cu_{0.5}Se_{0.5}. FIG. 13 is a phase diagram for different compositions of copper-selenium combinations.

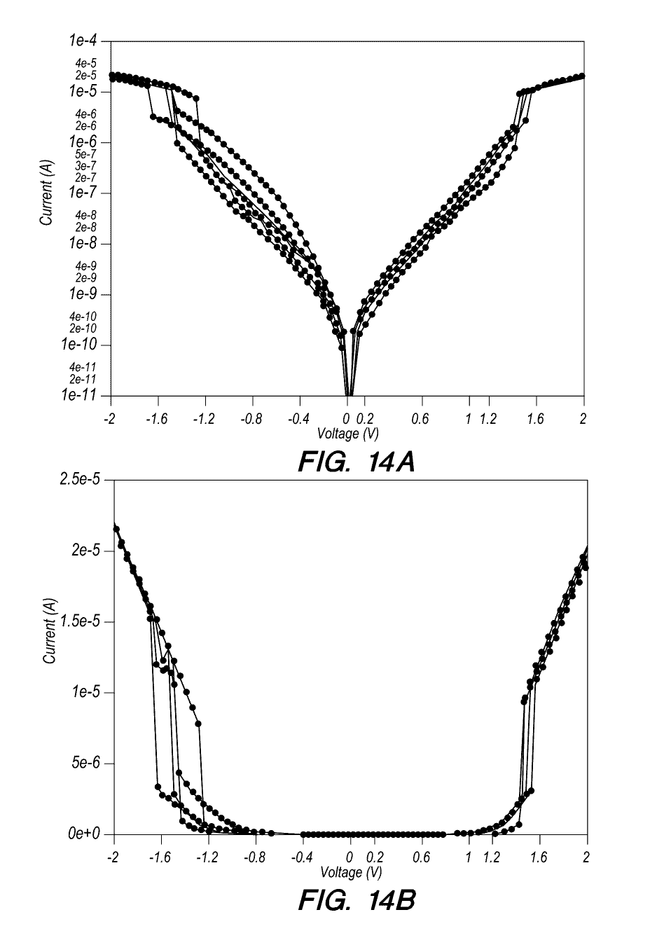

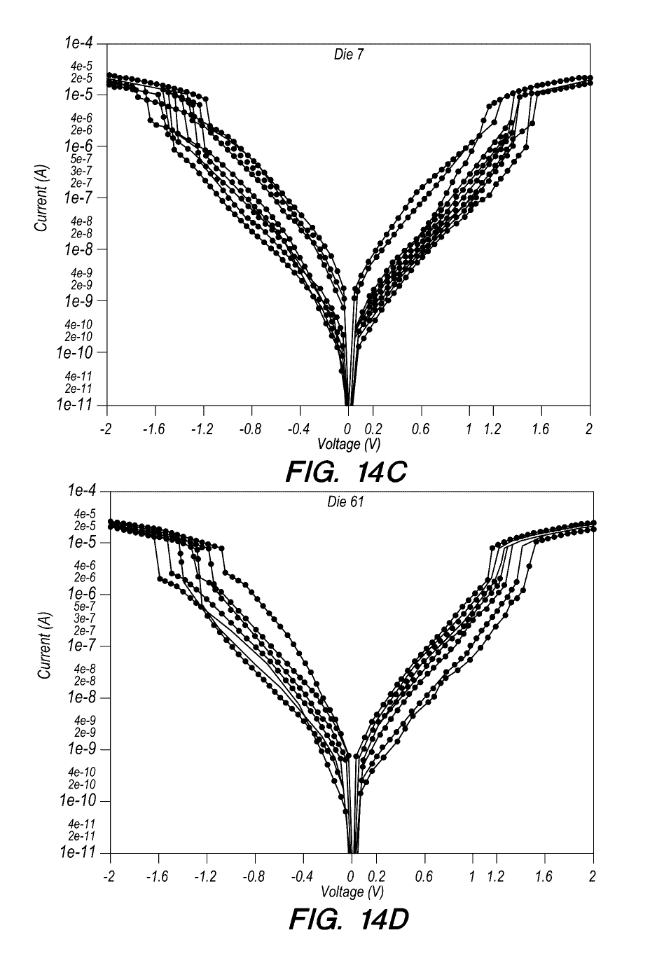

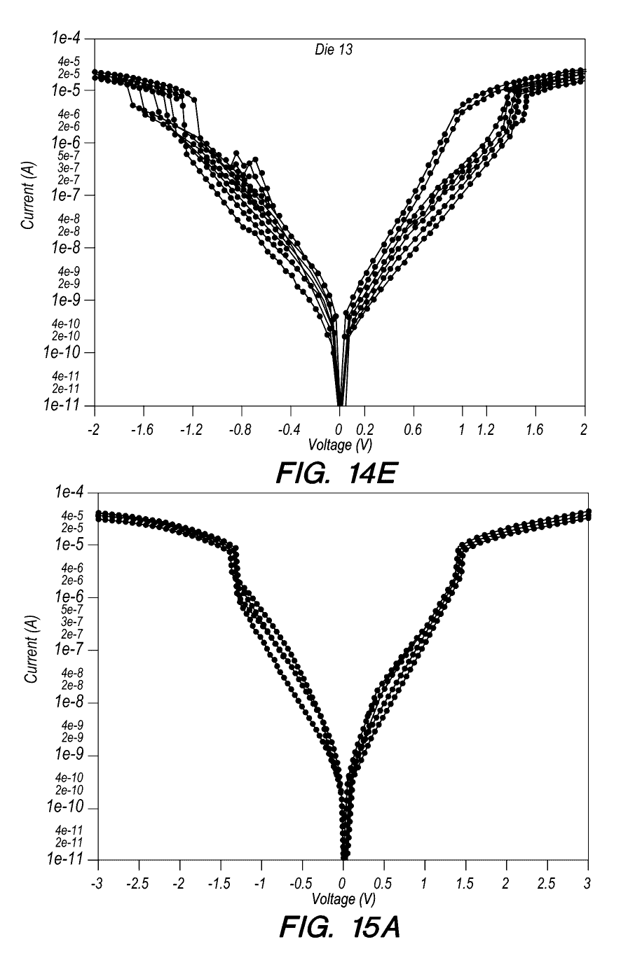

Additional examples of suitable materials for selector applications include Cu poor Ge₂₀Te₈₀, e.g. Cu₃Ge₁₅Te₈₂. FIGS. 14A-14B illustrate a symmetric selector-like behavior for Ge₂₀Te₈₀ materials, which had the highest targeted resistivity. FIGS. 14C-14E illustrate good device-to-device repeatability on different PVD spots/dies.

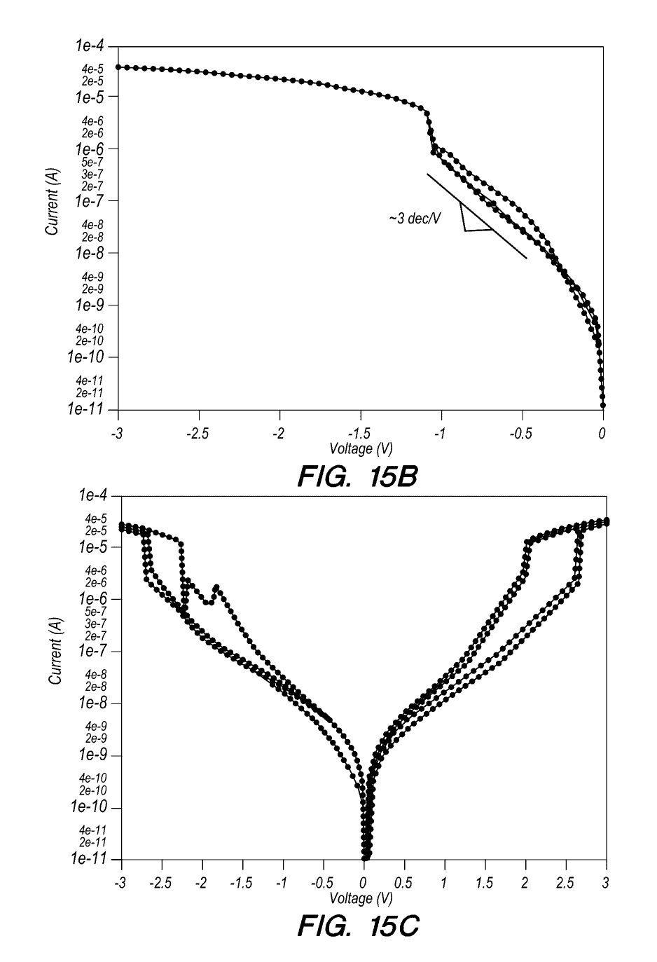

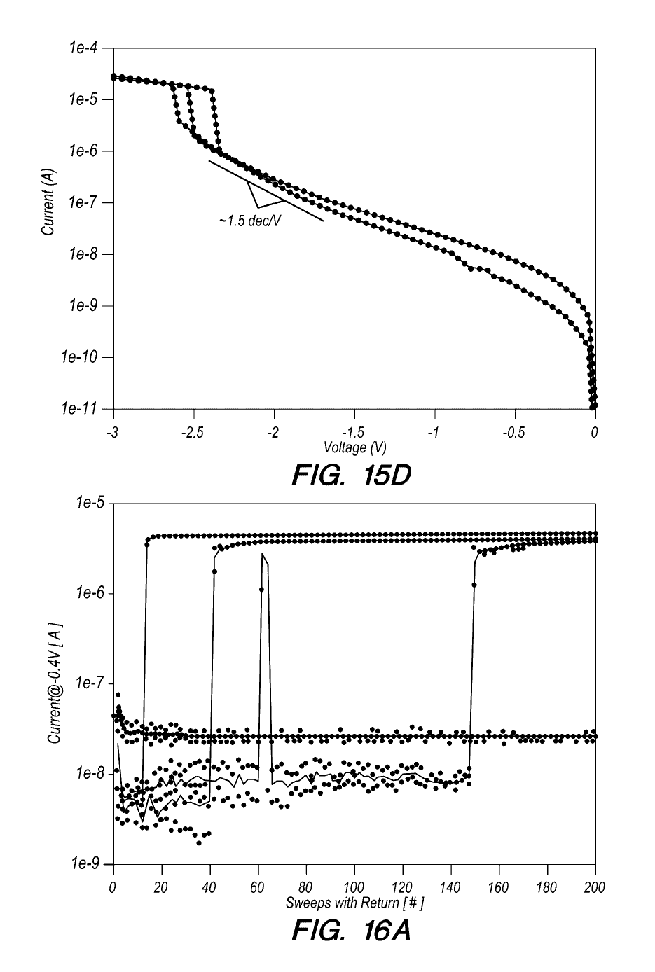

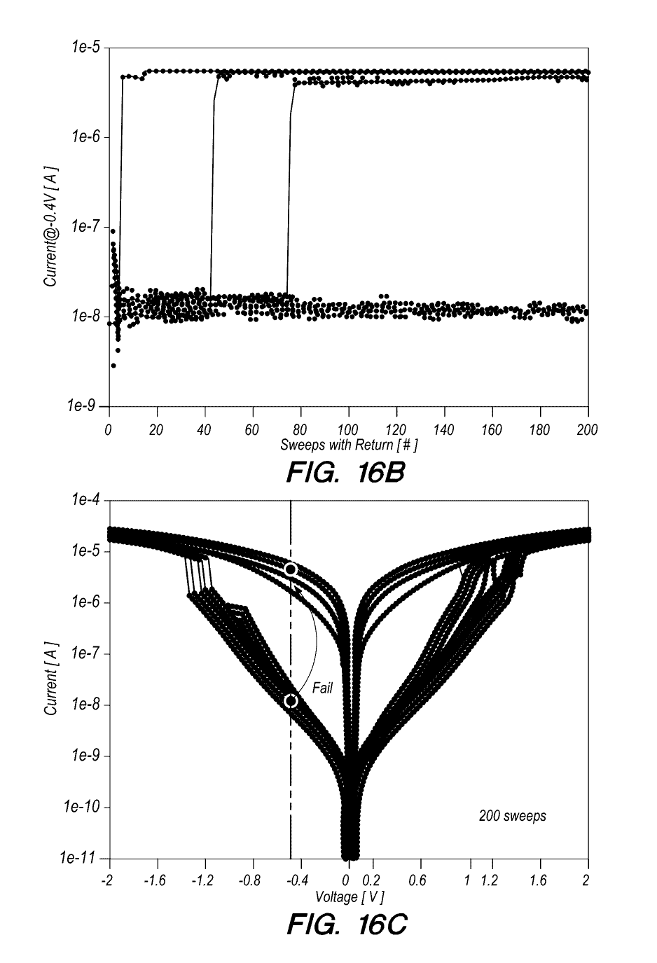

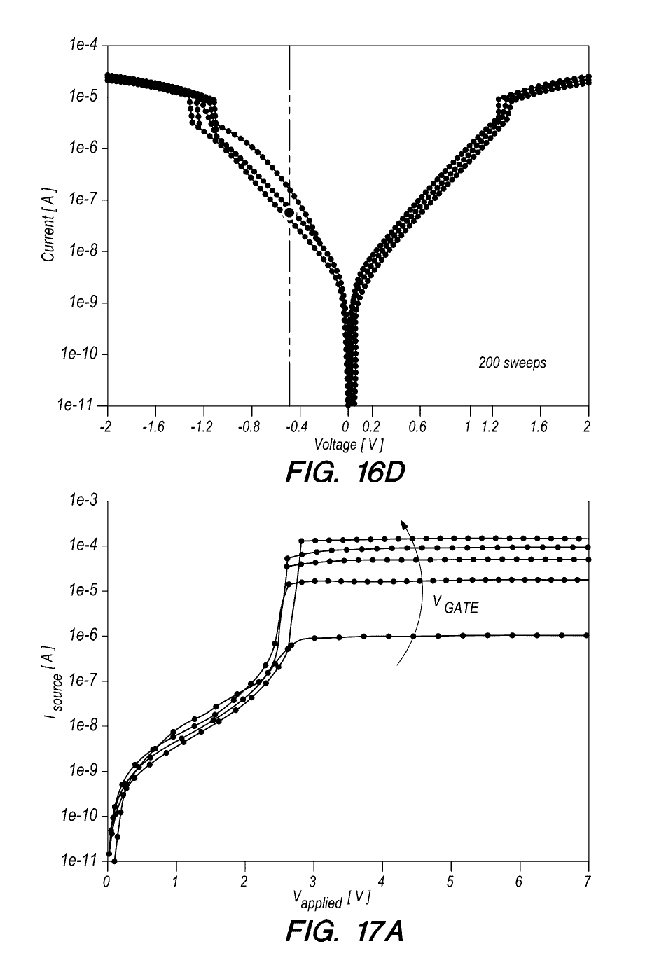

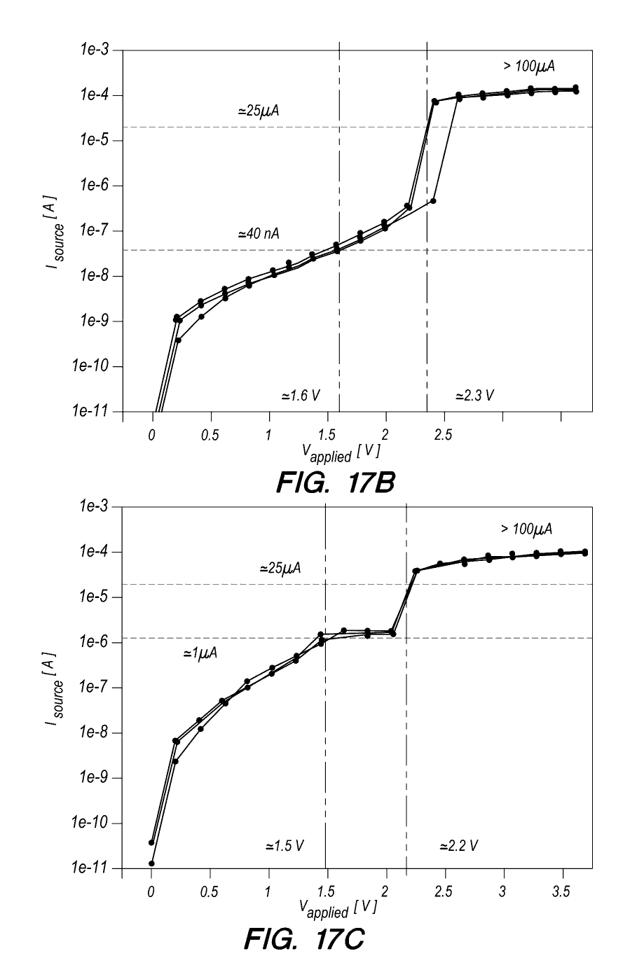

FIG. 15A-15D explore thickness dependence for Ge₂₀Te₈₀ class of materials with FIGS. 15A-15B showing I-V plots for bipolar and unipolar sweeps of 200 A thick sample and FIGS. 15C-15D showing I-V plots for bipolar and unipolar sweeps of 600 A thick sample. Endurance data is presented in FIGS. 16A-16D. The endurance failure mode in this experiment was permanent short. In this experiment larger BECs appeared to be more robust. Finally, FIGS. 17A-17C illustrate data for 1T1R structures tested to verify viability before reducing the size of the top electrode through patterning and etch. Again selector-like characteristic were observed for these compositions. Preliminary temperature experiments exhibit a conductivity increase with elevated temperature (room temperature to 85° C. as shown in I-V plots presented in FIGS. 17B and 17C).

Chalcopyrite is copper iron sulfide and it had been found to be effective for selector application described above. Reviewing some requirements for selectors may help to better appreciate applicability of chalcopyrites. Specifically, selectors need to have low initial Iₗₑₐₖ, low VNL, diode-like conduction (non-snapping), symmetry as a function of polarity, and elastic (non-memory) characteristics. Other considerations in selecting materials for selector elements include film thickness, ability to operate with an inert electrode, thermal budget of less than 350 C, and ability for area scaling desirable. Behavior observed for some traditional device types indicate that doped crystalline semiconductors may be needed. Furthermore, these types of semiconductors may be operated at high voltages

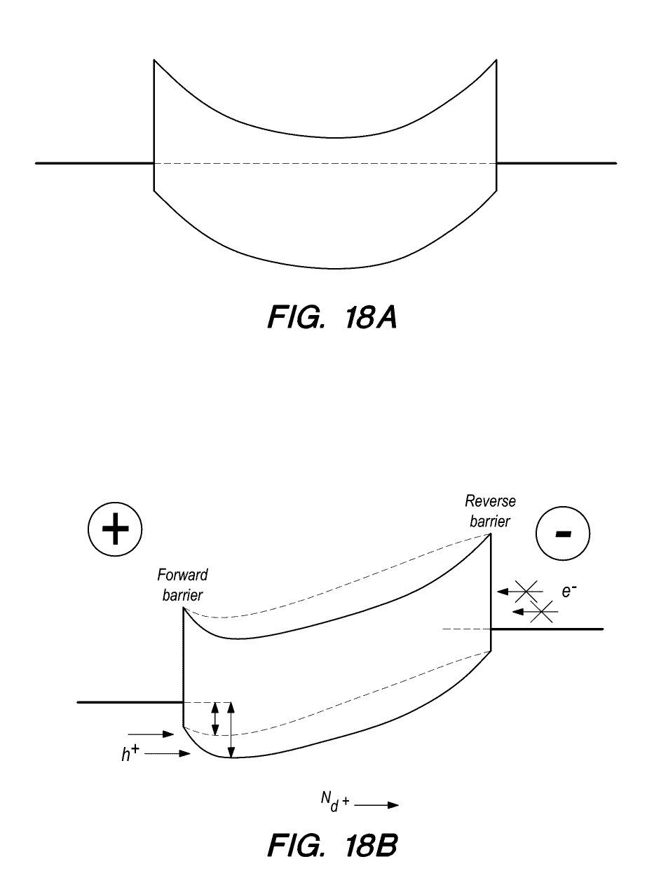

Operating mechanism is schematically presented in FIGS. 18A-18B. From the electrical point of view, the diode is similar to two modulated Schottky diodes connected back-to-back. The symmetry in this type of devices is viewed as a function of polarity. FIG. 18A is an equivalent band diagram at zero bias. As shown in this diagram, at zero and low bias (below VNL) band diagram is similar to the two Schottky diodes connected back-to-back. Majority carrier conduction is suppressed by Schottky barriers. Low initial Iₗₑₐₖ is demonstrated. FIG. 18B is an equivalent band diagram with applied high bias (above V_{NL}). At a high bias (above V_{NL}), majority carrier conduction suppressed by reverse Schottky barrier. Minority carrier conduction from forward barrier becomes relevant where the equivalent change in doping concentration due to ionic movement diminish the barrier. This provides the diode-like conduction and low VNL.

Structure and function of BARITT (barrier injection transit time) diodes support assumptions to mechanism interpretation. The reasoning presented above appears to be consistent with the BARITT (barrier injection transit time) diode. Some fundamental assumptions to the mechanism interpretation that has been considered include (a) approximate amorphous semiconductor band diagram with crystalline semiconductor band diagram, (b) not consider presence of Fermi level pinning, (c) consider amorphous extrinsic semiconductor, (d) consider symmetric stack (materials and geometry), (e) ese of inert electrodes, and (f) local concentration of dopants/ions modified by field.

For example, the active component can have a graded band gap, (e.g., a band gap having graded electron energy level), so that at low applied voltages, the effective thickness of the active component, accounted for the band bending effect due to the applied voltage, can remain large enough to prevent high tunneling or thermionic current. The graded band gap can be further configured so that at low applied voltages, the effective thickness of the active component can be adequate to allow high tunneling or thermionic current.

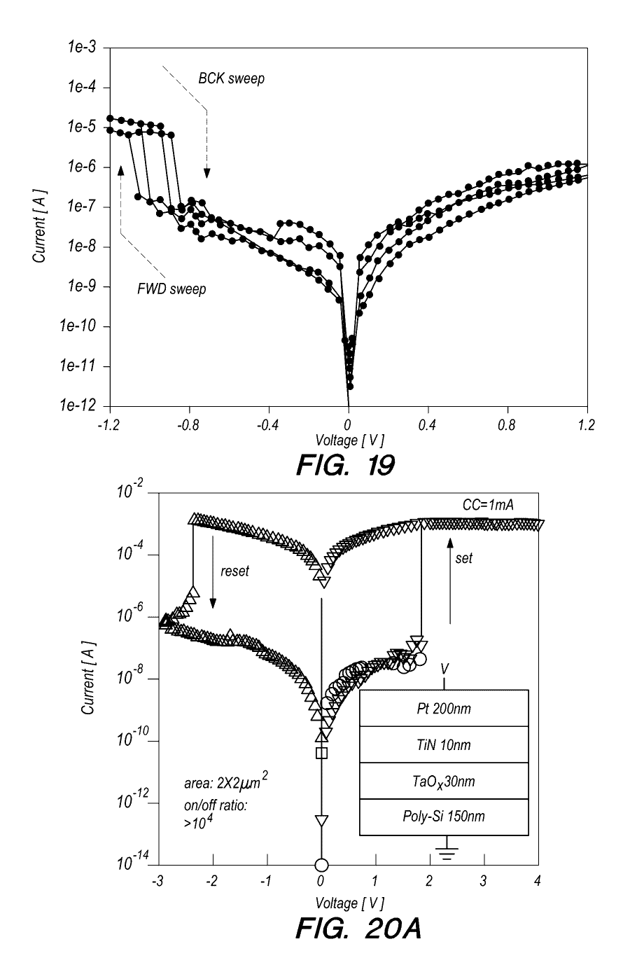

In traditional semiconductors, dopants are introduced by thermal diffusion or ion implantation (both of them are high energy process). At the same time, local changes in dopant concentration have been observed, at room temperature, as a result of application of electric field. Semiconducting compounds with a relative mobile component may be referred herein as “semionics.” A class of material suitable for semionic applications is the chalcopyrite: IB-IIIA-VIA₂, e.g. (Cu,Ag)(Al,Ga,In,Tl)(Se,S,Te)₂. FIG. 19 illustrates test data for one example of chalcopyrite-based memory selector, i.e. Cu_{0.51}Ge_{0.1}Se_{0.39}.

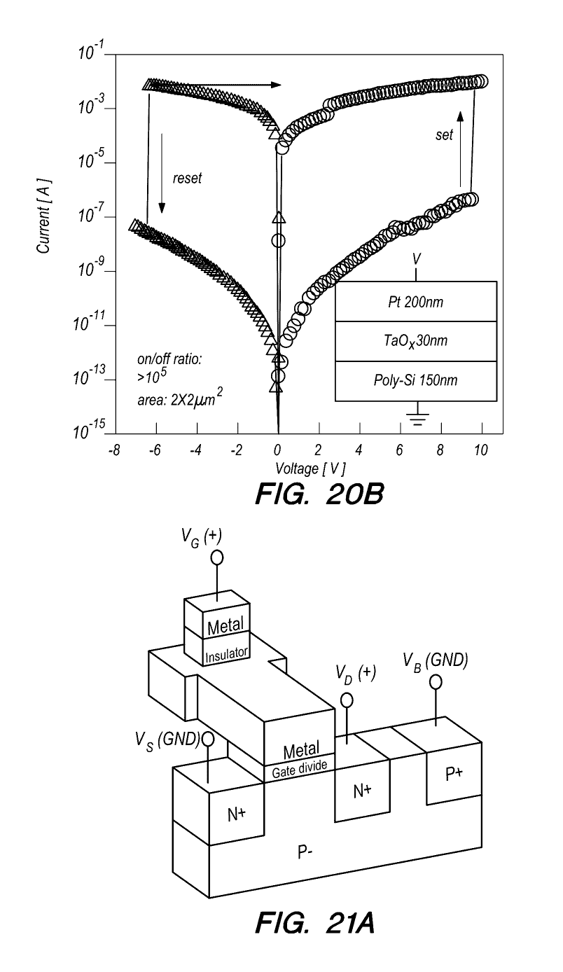

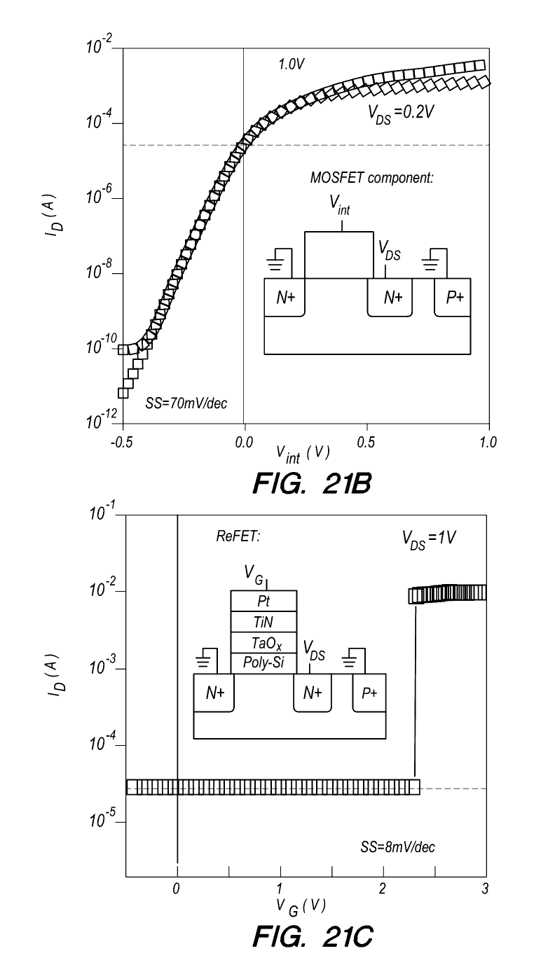

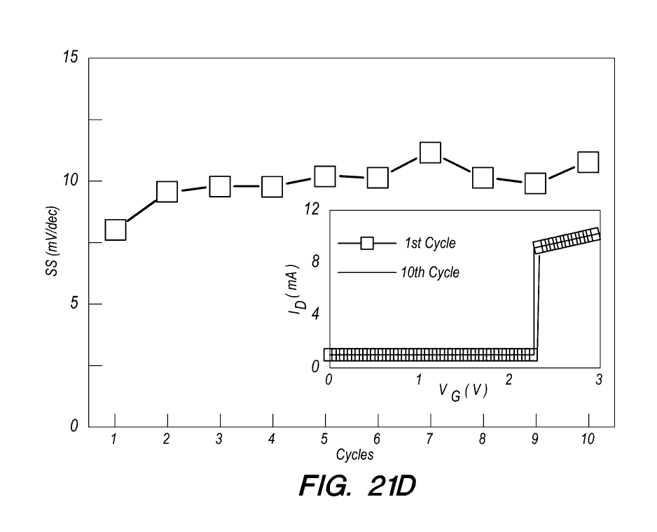

A MIM stack can be replaced by a device showing selector behavior to yield no or minimal hysteresis and achieve some desirable for logic operation as for example shown in FIGS. 20A-20B and 21A-21D.

### Examples of Assemblies Using Selector Elements

In some embodiments, a selector element may be connected in series with a memory element, collective forming an assembly or memory devices. Some examples of memory elements include, but are not limited to, magneto-resistive random access memory (MRAM), ferroelectric random access memory (FRAM), phase change memory (PCM), spin transfer torque random access memory (STT-RAM), and resistive random access memory (ReRAM), among others.

Resistive memory devices formed using ReRAM elements have two or more stable states with different resistances. Specifically, bistable resistive memory devices have two stable states. A bistable memory element can be placed in a high resistance state or a low resistance state by application of suitable voltages or currents. Voltage pulses are typically used to switch the memory element from one resistance state to the other. Nondestructive read operations can be performed to ascertain the value of a data bit that is stored in a memory cell.

Resistive switching based on transition metal oxide switching elements formed of metal oxide films has been demonstrated. Although metal oxide films such as these exhibit bi-stability, the resistance of these films and the ratio of the high-to-low resistance states are often insufficient to be of use within a practical nonvolatile memory device. For instance, the resistance states of the metal oxide film should preferably be significant as compared to that of the system (e.g., the memory device and associated circuitry) so that any change in the resistance state change is perceptible. The variation of the difference in resistive states is related to the resistance of the resistive switching layer. Therefore, a low resistance metal oxide film may not form a reliable nonvolatile memory device. For example, in a nonvolatile memory that has conductive lines formed of a relatively high resistance metal such as tungsten, the resistance of the conductive lines may overwhelm the resistance of the metal oxide resistive switching element. Therefore, the state of the bistable metal oxide resistive switching element may be difficult or impossible to sense. Furthermore, the parasitic resistance (or the parasitic impedance, in the actual case of time-dependent operation), (e.g. due to sneak current paths that exist in the system), may depend on the state of the system, such as the data stored in other memory cells. It is often preferable that the possible variations of the parasitic impedance be unsubstantial compared to the difference in the values of the high and low resistance of a memory cell.

Similar issues can arise from integration of the resistive switching memory element with current selector elements (also known as current limiter or current steering elements), such as diodes and/or transistors. Control elements (e.g. selector devices) in nonvolatile memory structures can screen the memory elements from sneak current paths to ensure that only the selected bits are read or programmed. Schottky diode can be used as a selector device, which can include p-n junction diode or metal-semiconductor diode, however, this requires high thermal budget that may not be acceptable for 3-dimensional (3D) memory application. Metal-Insulator-Metal Capacitor (MIMCAP) tunneling diodes may have a challenge of providing controllable low barrier height and low series resistance. In some embodiments, the control element can also function as a current limiter or steering element. In some embodiments, a control element can suppress large currents without affecting acceptable operation currents in a memory device. For example, a control element can be used with the purpose of increasing the ratio of the measured resistances in the high and low resistance state, further making the non-volatile memory device less susceptible to the noise due to parasitic impedances in the system. Note that the terms “control element”, “current selector”, “current limiter”, and “steering element” may often times be substituted for each other, due to a substantial overlap in the functional utility of the elements they may describe. Such a substitution does not affect the scope of this description, which is limited only by the claims.

A cross-bar architecture is promising for future non-volatile memories such as phase change memory (PCM) or resistive random access memory (ReRAM) because of the small cell size of 4F² achievable with each cell at the intersections of perpendicular word lines and bit lines, and the potential to stack multiple layers to achieve very high memory density. Two key challenges for the cross bar architecture are the possibility of current sneak-through paths (e.g., when trying to read a cell in a high resistance state adjacent to cells in a low resistance state) and the need to avoid unselected cell modification when half of the switching voltage is applied to the selected cell.

To reduce or eliminate the sneak path occurrence, a selector element is used in the cross point memory array. For example, a selector element can be located in each memory cell. The selector element can isolate the selected memory cell from unselected memory cells by breaking parallel connections of the memory cells.

### DEFINITIONS

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “substrate” as used herein may refer to any workpiece on which formation or treatment of material layers is desired. Substrates may include, without limitation, float glass, low-iron glass, borosilicate glass, display glass, alkaline earth boro-aluminosilicate glass, fusion drawn glass, flexible glass, specialty glass for high temperature processing, polyimide, plastics, polyethylene terephthalate (PET), etc. for either applications requiring transparent or non-transparent substrate functionality.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, a material (e.g. a dielectric material or an electrode material) will be considered to be “crystalline” if it exhibits greater than or equal to 30% crystallinity as measured by a technique such as x-ray diffraction (XRD).

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, elements described or labeled by the phrases “control element”, “selector”, “current limiter”, and “current steering device” will be understood to be equivalent and will be used interchangeably.

As used herein, the phrase “sneak current” and “sneak-through current” will be understood to be equivalent and will be used interchangeably and will be understood to refer to current flowing through non-selected memory cells during a read operation.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A selector element comprising:
a first electrode;
a second electrode; and
an active component disposed between the first electrode and the second electrode,
wherein the active component comprises an insulating matrix and mobile ions.

2. The selector element of claim 1, wherein the selector element is a bipolar selector element.

3. The selector element of claim 1, wherein the insulating matrix and the mobile ions comprise copper and one of germanium (Ge), selenium (Se), or tellerium (Te).

4. The selector element of claim 3, wherein the insulating matrix and the mobile ions comprises copper and selenium (Se), and wherein a Se:Cu atomic ratio is between 75:25 and 50:50.

5. The selector element of claim 3, wherein the insulating matrix and the mobile ions comprises one of Se₆₁Cu₃₉, Se₆₇Cu₃₃, or Se₅₆Cu₄₄.

6. The selector element of claim 3, wherein the first electrode directly interfaces the active component and comprises one of copper or tungsten.

7. The selector element of claim 6, wherein the second electrode directly interfaces the active component and comprises copper.

8. The selector element of claim 6, wherein the second electrode comprises titanium nitride.

9. The selector element of claim 1, wherein the insulating matrix and the mobile ions are arranged into a multilayered structure of the active component, and wherein at least one layer of the multilayered structure has a different composition than at least one other layer of the multilayered structure.

10. The selector element of claim 8, wherein the multilayered structure comprises a first layer, a second layer, and a third layer such that the second layer is disposed between the first layer and the third layer, and wherein a concentration of the mobile ions in the second layer is greater than that in the first layer and in the third layer.

11. The selector element of claim 10, wherein the concentration of the mobile ions in the first layer is substantially the same as the concentration of the mobile ions in the third layer.

12. The selector element of claim 10, wherein the first layer has a composition of Ge₃₃Se₂₄Cu₄₇, wherein the second layer has a composition of Ge₄₇Se₂₉Cu₂₄, and wherein the third layer has a composition of Ge₃₃Se₂₄Cu₄₇.

13. The selector element of claim 9, wherein the multilayered structure comprises a first layer having a composition of Ge₁₃Se₈Cu₇₉ and a second layer having a composition of Ge₆₂Se₃₈.

14. The selector element of claim 1, wherein the mobile ions are dispersed within the insulating matrix.

15. The selector element of claim 1, wherein the mobile ions and the insulating matrix form a non-homogeneous mixture.

16. The selector element of claim 1, wherein the mobile ions and the insulating matrix form a homogeneous mixture.

17. The selector element of claim 1, wherein the active component further comprises a matrix modifier comprising one of tungsten, nitrogen, or oxygen.

18. The selector element of claim 1, wherein the mobile ions for a layer directly interfacing the insulating matrix.

19. A method of operating a bipolar selector element, the method comprising:
applying a voltage to the bipolar selector element above a threshold voltage,
wherein the bipolar selector element comprises a first electrode, a second electrode and an active component disposed between the first electrode and the second electrode and comprising an insulating matrix and mobile ions,
wherein the voltage is applied between first electrode and the second electrode,
wherein a potential of the first electrode is greater than a potential of the second electrode, and
wherein a resistance of the bipolar selector element reduces when the voltage is applied above the threshold voltage; and
reducing the voltage applied to the bipolar selector element below the threshold voltage,
wherein the resistance of the bipolar selector element increases when the voltage falls below the threshold voltage.

20. The method of claim 19, further comprising, after reducing the voltage applied to the bipolar selector element below the threshold voltage,
applying the voltage to the bipolar selector element above the threshold voltage,
wherein the voltage is applied between first electrode and the second electrode,
wherein the potential of the first electrode is less than the potential of the second electrode, and
wherein the resistance of the bipolar selector element is same as when the potential of the first electrode is greater than the potential of the second electrode.
